(19) United States
(12) Patent Application Publication
(10) Pub. No.: US 2026/0040992 A1
(43) Pub. Date: Feb. 5, 2026

(54) SEMICONDUCTOR PACKAGE

(71) Applicant: Samsung Electronics Co., Ltd., Suwon-si (KR)

(72) Inventors: Taejun JEON, Suwon-si (KR); Yonghyun KIM, Suwon-si (KR); GEUNWOO KIM, Suwon-si (KR); HYUNHO CHU, Suwon-si (KR)

(21) Appl. No.: 19/031,446

(22) Filed: Jan. 18, 2025

(30) Foreign Application Priority Data
Aug. 5, 2024 (KR) 10-2024-0104224

(51) Int. Cl. H01L 23/00; H01L 21/56; H01L 23/31; H01L 25/16; H10B 80/00; H10D 80/30

(52) U.S. Cl. CPC H01L 24/48; H01L 23/3135; H01L 24/04; H01L 24/05; H01L 24/32; H01L 24/73; H01L 25/16; H01L 21/56; H01L 2224/04042; H01L 2224/05557; H01L 2224/05559; H01L 2224/32145; H01L 2224/32225; H01L 2224/48091; H01L 2224/48147; H01L 2224/48227; H01L 2224/73215; H01L 2224/73265; H01L 2225/06506; H01L 2225/0651; H01L 2225/06562; H01L 2924/1815; H10B 80/00; H10D 80/30

(57) ABSTRACT

A semiconductor package includes a package substrate, a chip stack having first semiconductor chips stacked on the package substrate, a first molding film covering the chip stack on the package substrate, a first connection wire vertically penetrating the first molding film to be connected to the package substrate, and exposed onto an upper surface of the first molding film, a second semiconductor chip disposed on the first molding film, and having a first chip pad disposed on one surface facing the package substrate, a second molding film covering the second semiconductor chip on the first molding film, and a connection terminal connecting the first chip pad and an upper end of the first connection wire.

### CROSS-REFERENCE TO RELATED APPLICATIONS

This U.S. non-provisional patent application claims priority under 35 U.S.C. § 119 of Korean Patent Application No. 10-2024-0104224, filed on Aug. 5, 2024, the entire contents of which are hereby incorporated by reference.

### BACKGROUND

The present disclosure relates to a semiconductor package having stacked chips and wires for connecting the same.

With development of the electronics industry, demand for high-performance, high-speed, and miniaturization of an electronic component is increasing. In response to this trend, recent packaging technology is enabling the integration of a plurality of semiconductor chips within a single package.

A semiconductor package is an integrated circuit chip implemented in a form suitable for using in an electronic product. In general, the semiconductor package is manufactured by mounting a semiconductor chip on a print circuit board (PCB), and electrically connecting the same by using a bonding wire or bump. With the recent advancements in the electronics industry, the semiconductor package is evolving towards goals such as miniaturization, weight reduction, and cost-effective manufacturing. As an application field thereof expands to a large-capacity storage means, various types of semiconductor packages are emerging.

As semiconductor chips become highly integrated, sizes of the semiconductor chips are gradually decreasing. However, as semiconductor chips shrink in size, attaching a desired number of solder balls to the semiconductor chips, as well as handling and testing the semiconductor chips, becomes increasingly challenging. In addition, there is a limitation of having to diversify the board on which the semiconductor chip is mounted depending on the size of the semiconductor chip. In order to solve this, a fan-out package is suggested.

### SUMMARY

The present disclosure provides a semiconductor package with improved structural stability.

The present disclosure also provides a semiconductor package with improved thermal stability.

A technical goal of the inventive concept is not limited to the goal mentioned above, and other technical goals that are not mentioned may be clearly understood from description below by those skilled in the art.

According to an aspect of the present disclosure, a semiconductor package includes a package substrate, a chip stack having first semiconductor chips stacked on the package substrate, a first molding film covering the chip stack on the package substrate, a first connection wire vertically penetrating the first molding film and connected to the package substrate, wherein the first connection wire is exposed at an upper surface of the first molding film, a second semiconductor chip disposed on the first molding film, and having a lower surface and a first chip pad, wherein the first chip pad is disposed at the lower surface of the second semiconductor chip, a second molding film disposed on the first molding film and covering the second semiconductor chip, and a connection terminal connecting the first chip pad to an upper end of the first connection wire.

According to an aspect of the present disclosure, a semiconductor package includes a package substrate, a chip stack including first semiconductor chips stacked on the package substrate, a first molding film disposed on the package substrate and encapsulating the chip stack, a second semiconductor chip disposed on the first molding film, a second molding film disposed on the first molding film and encapsulating the second semiconductor chip, a first connection wire vertically penetrating the first molding film, and electrically connected to the second semiconductor chip, and external terminals connected to a lower surface of the package substrate, wherein the chip stack is spaced apart from the first connection wire in a horizontal direction parallel to an upper surface, opposite to the lower surface, of the package substrate, and wherein each of the first semiconductor chips has an upper surface and a chip pad disposed at the upper surface of each first semiconductor chip, and second connection wires connecting the chip pads of the first semiconductor chips with each other.

According to as aspect of the present disclosure, a semiconductor package includes a package substrate, a chip stack having first semiconductor chips stacked on an upper surface of the package substrate, and first connection wires connecting the first semiconductor chips, a second connection wire disposed on the upper surface of the package substrate, spaced apart from the chip stack in a horizontal direction parallel to the upper surface of the package substrate, and connected to a substrate pad of the package substrate, a first molding film disposed on the upper surface of the package substrate and encapsulating the chip stack and the second connection wire, a second semiconductor chip disposed on the first molding film, and connected to an upper end of the second connection wire by using a solder member, and a second molding film disposed on the first molding film and encapsulating the second semiconductor chip.

According to an aspect of the present disclosure, a method of manufacturing a semiconductor package includes stacking first semiconductor chips on a package substrate, forming first connection wires connecting the first semiconductor chips and the package substrate, forming, on the package substrate, a second connection wire vertically extending from an upper surface of the package substrate such that the second connection wire is spaced apart from the first semiconductor chips, forming, on the package substrate, a first molding film embedding the first semiconductor chips and the second connection wire, exposing an upper end of the second connection wire by partially removing the first molding film, supplying solder paste in contact with the upper end of the second connection wire, placing a second semiconductor chip on the first molding film, connecting the second semiconductor chip to the second connection wire by using the solder paste, and forming, on the first molding film, a second molding film embedding the second semiconductor chip.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view for describing a semiconductor package according to embodiments of the inventive concept;

FIG. 2 is an enlarged diagram of region A of FIG. 1;

FIGS. 3 to 5 are enlarged diagrams of region B of FIG. 1;

FIG. 6 is a cross-sectional view for describing a semiconductor package according to embodiments of the inventive concept;

FIG. 7 is an enlarged diagram of region C of FIG. 6;

FIGS. 8 to 11 are cross-sectional views for describing a semiconductor package according to embodiments of the inventive concept; and

FIGS. 12 to 23 are cross-sectional views for describing a method of manufacturing a semiconductor package according to embodiments of the inventive concept.

### DETAILED DESCRIPTION

A semiconductor package according to the inventive concept will be described with reference to the drawings.

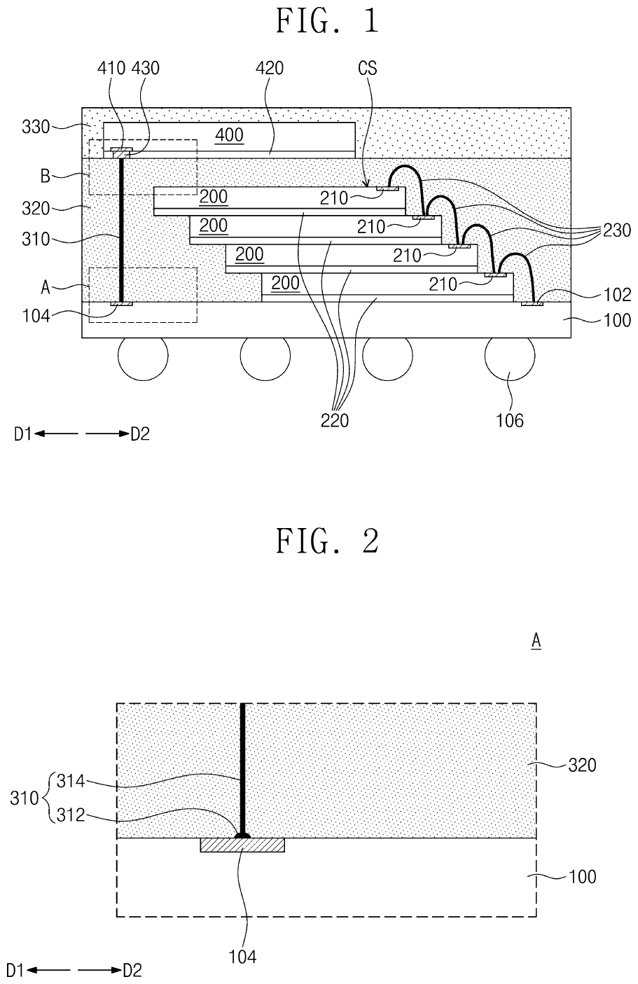

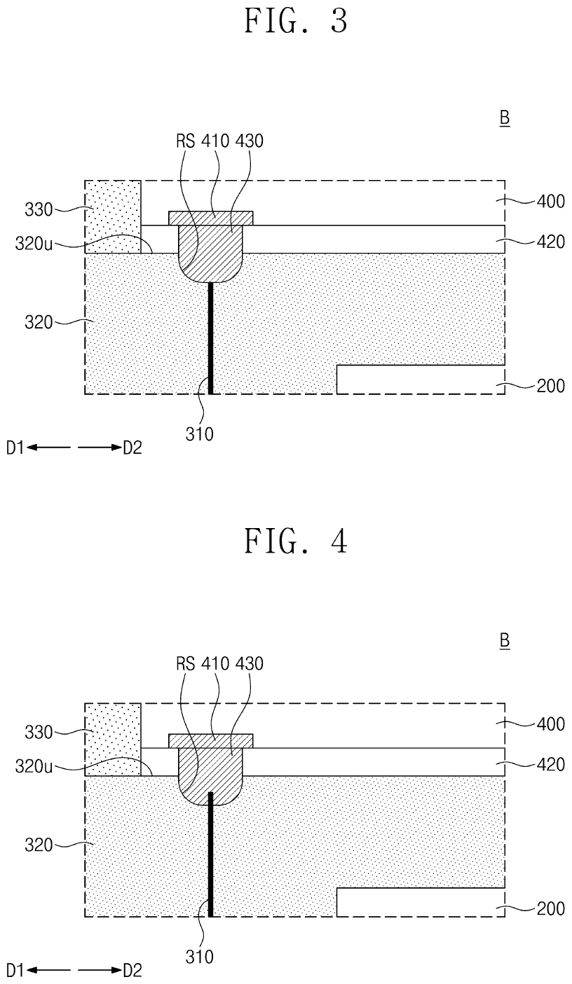

FIG. 1 is a cross-sectional view for describing a semiconductor package according to embodiments of the inventive concept. FIG. 2 is an enlarged diagram of region A of FIG. 1. FIGS. 3 to 5 are enlarged diagrams of region B of FIG. 1.

Referring to FIG. 1, a package substrate 100 may be provided. The package substrate 100 may be a print circuit board (PCB) having a signal pattern provided on an upper surface of the package substrate 100. The signal pattern may include first and second substrate pads 102 and 104. The first substrate pad 102 may be horizontally spaced apart from the second substrate pad 104. The first substrate pad 102 may be a pad for connecting first semiconductor chips 200 to the package substrate 100. The second substrate pad 104 may be a pad for connecting a second semiconductor chip 400 to the package substrate 100. The first semiconductor chips 200 and the second semiconductor chip 400 will be described below. Each of the first substrate pad 102 and the second substrate pad 104 may be provided in plurality as needed. The package substrate 100 may have a structure in which line layers are stacked on a core pattern. In an embodiment, the line layers may be stacked on each of an upper surface and a lower surface of the core pattern.

According to other embodiments, the package substrate 100 may be a redistribution substrate. For example, the package substrate 100 may include at least two substrate line layers mutually stacked. In the present specification, the substrate line layer may mean a line layer formed by patterning each of one insulating material layer and one conductive material layer. For example, conductive patterns in one substrate line layer may be horizontally extending lines, and may not vertically overlap each other. Each of the substrate line layers may include substrate insulating patterns and substrate line patterns in the substrate insulating patterns. The substrate line patterns of any one substrate line layer and the substrate line patterns of another adjacent substrate line layer may be electrically connected with each other.

External terminals 106 may be provided on a lower surface of the package substrate 100. The external terminals 106 may include a solder ball, a solder bump or a solder pad. The package substrate 100 may include a ball grid array (BGA), a fine ball grid array (FBGA) or a land grid array (LGA) depending on types of the external terminals 106.

A chip stack CS may be provided on the package substrate 100. The chip stack CS may have a plurality of first semiconductor chips 200 mutually stacked in a vertical direction. A lowermost semiconductor chip of the first semiconductor chips 200 of the chip stack CS is referred to as the lowermost first semiconductor chip 200, and an uppermost semiconductor chip of the first semiconductor chips 200 of the chip stack CS is referred to as the uppermost first semiconductor chip 200. In the present specification, for convenience of description, the uppermost or lowermost first semiconductor chip 200 is only separately referred to as a semiconductor chip disposed at the top or bottom of the chip stack CS. Although the first semiconductor chips 200 are referred to as different names, the first semiconductor chips 200 may not necessarily represent different chips. The first semiconductor chips 200 may be either the same as or distinct from each other. For example, the first semiconductor chips 200 may be a memory chip such as DRAM, SRAM, MRAM, and flash memory. Alternatively, the lowermost first semiconductor chip 200 may be a logic chip, and the remaining first semiconductor chips 200 may be memory chips. FIG. 1 illustrates the chip stack CS having four first semiconductor chips 200, but the inventive concept is not limited thereto. The chip stack CS may have three or less or five or more first semiconductor chips 200.

Describing on the basis of one first semiconductor chip 200, the first semiconductor chip 200 may have a front surface and a rear surface opposite to the front surface. Hereinafter, in the present specification, the front surface is an active surface of an integrated element in a semiconductor chip, and may be defined as a surface on which pads of the semiconductor chip are formed, and the rear surface may be defined as an opposite surface of the front surface. A lower surface of the first semiconductor chip 200 may be the rear surface, and an upper surface of the first semiconductor chip 200 may be the front surface. For example, the first semiconductor chips 200 may be disposed in a face up form. The first semiconductor chips 200 may have a first chip pad 210 provided on the upper surface. The first chip pad 210 may be electrically connected to an integrated circuit of the first semiconductor chip 200.

FIG. 1 illustrates that each of the first semiconductor chips 200 has one first chip pad 210, but only one first chip pad 210 is illustrated in FIG. 1 which is a cross-sectional view, and the first semiconductor chips 200 may each have a plurality of first chip pads 210 as needed.

The first semiconductor chips 200 may be disposed in an offset stack structure. For example, the first semiconductor chips 200 may be stacked at an incline in a first direction D1 parallel to the upper surface of the package substrate 100 and may form an upward-sloping staircase form (i.e., a cascade form). For example, each of the first semiconductor chips 200 may protrude outward in the first direction D1 from another first semiconductor chip 200 located thereunder or located directly beneath it. For example, each of the first semiconductor chips 200 may shift toward the second connection wire 310 relative to another first semiconductor chip 200 directly beneath it.

As the first semiconductor chips 200 stack in the staircase form, a portion (hereinafter, the portion will be referred to as an exposed surface) of the upper surface of each of the first semiconductor chips 200 may be exposed. According to an offset stack direction of the first semiconductor chips 200, the exposed surface of the first semiconductor chip 200 may be located adjacent to a side surface in a second direction D2 of another first semiconductor chip 200 located thereon. The offset stack direction is defined as a direction in which when semiconductor chips are stacked, a semiconductor chip is shifted with respect to another semiconductor chip located thereunder. The second direction D2 is defined as an opposite direction of the first direction D1. For example, the offset stack direction of the first semiconductor chips 200 may be the first direction D1 in FIG. 1. The upper surface of the first semiconductor chips 200 may be an active surface. For example, the first chip pad 210 of each of the first semiconductor chips 200 may be provided on the exposed surface in the upper surface of the first semiconductor chips 200. For example, the first chip pad 210 of each of the first semiconductor chips 200 may be located in the second direction D2 from another first semiconductor chip 200 located thereon.

First adhesive layers 220 may be respectively provided on the lower surfaces of the first semiconductor chips 200. The first semiconductor chips 200 may be adhered to other first semiconductor chips 200 located thereunder by using the first adhesive layers 220. For example, the first semiconductor chips 200 may be adhered to an upper surface of the other first semiconductor chip 200, or the upper surface of the package substrate 100 located thereunder by using the first adhesive layers 220. The first adhesive layers 220 may each include a die attach film (DAF).

The first semiconductor chips 200 may be wire-bonded to the package substrate 100. The first semiconductor chips 200 may be connected to the package substrate 100 through first connection wires 230. For example, the first connection wires 230 may connect the first chip pads 210 of the first semiconductor chips 200 to the first substrate pads 102 of the package substrate 100. Some of the first connection wires 230 may connect the first chip pads 210 of two adjacent first semiconductor chips 200 with each other. Others of the first connection wires 230 may connect one first chip pads 210 of the first semiconductor chips 200 to the first substrate pads 102 of the package substrate 100. For example, the first semiconductor chip 200 connected to the package substrate 100 may be a lowermost first semiconductor chip 200 of the first semiconductor chips 200, but the inventive concept is not limited thereto. When each of the first semiconductor chips 200 has a plurality of first chip pads 210, or the package substrate 100 has a plurality of first substrate pads 102, the first connection wire 230 may be provided in plurality for connection therebetween. For example, two first semiconductor chips 200 adjacent to each other may be electrically connected with each other by using the plurality of first connection wires 230.

Although not shown, each of the first connection wires 230 may be bonded to the first chip pad 210 or the first substrate pad 102 in a stitch bonding manner or a ball bonding manner. For example, each of the first connection wires 230 may include bonding portions adhered to an upper surface of the first chip pads 210 or an upper surface of the first substrate pad 102, and a wire loop extending from the bonding portions and connecting the bonding portions with each other or the first substrate pad 102 to a bonding portion adjacent thereto. The bonding portions may have a ball shape or a folding shape. The bonding portions may have a greater width than the wire loop.

A second connection wire 310 may be provided on the upper surface of the package substrate 100. The second connection wire 310 may be located at one side of the first direction D1 from the chip stack CS, but the inventive concept is not limited thereto. The second connection wire 310 may be horizontally spaced apart from the chip stack CS and the first substrate pad 102. The second connection wire 310 may be connected to the package substrate 100. For example, the second connection wire 310 may be connected to the second substrate pad 104 of the package substrate 100.

As illustrated in FIG. 2, the second connection wire 310 may be bonded to the second substrate pad 104 in a stitch bonding manner or a ball bonding manner. For example, the second connection wire 310 may include a bonding portion 312 adhered to an upper surface of the second substrate pad 104, and a wire loop 314 extending from the bonding portion 312. The bonding portion 312 may have a ball shape or a folding shape. The bonding portion 312 may have a greater width than the wire loop 314. For example, the bonding portion 312 may have a first width in a horizontal direction parallel to an upper surface of the package substrate 100, and the wire loop 314 may have a second width in the horizontal direction, which is smaller than the first width of the bonding portion 312.

Referring to FIGS. 1 and 2 together, the second connection wire 310 may extend upward from the upper surface of the second substrate pad 104. An angle formed by the second connection wire 310 and the upper surface of the second substrate pad 104 may be about 80° to about 90°. In an embodiment, the angle between the second connection wire 310 and the upper surface of the second substrate pad 104 may be about 90°. For example, the second connection wire 310 may vertically extend from the upper surface of the second substrate pad 104. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

An upper end of the second connection wire 310, that is, an upper end of the wire loop 314 may be located at a higher level than an upper surface of the chip stack CS. In an embodiment, the upper end of the second connection wire 310 may be located at a higher level than an uppermost end of the first connection wires 230 provided in the chip stack CS. In an embodiment, the uppermost portion of the second connection wire 310 may be located at a higher level than an uppermost portion of the first connection wires 230 provided in the chip stack CS. The second connection wire 310 may have a greater thickness than the first connection wires 230.

A first molding film 320 may be provided on the package substrate 100. The first molding film 320 may surround the second connection wire 310 and the chip stack CS on the upper surface of the package substrate 100. The first molding film 320 may completely embed (i.e., completely encapsulate) the chip stack CS and the first connection wires 230 provided in the chip stack CS. For example, the chip stack CS and the first connection wires 230 may not be exposed at an upper surface of the first molding film 320. The present disclosure is not limited thereto. In an embodiment, the upper end of the second connection wire 310 may be exposed at the upper surface of the first molding film 320. This will be described in more detail with reference to FIGS. 3 to 5.

Referring to FIGS. 1 and 3 together, the first molding film 320 may have a recess region RS. For example, an upper surface 320u of the first molding film 320 may have the recess region RS recessed from the upper surface 320u of the first molding film 320 toward a lower surface of the first molding film 320. The recess region RS may be located on the second connection wire 310. For example, the recess region RS may expose the upper end of the second connection wire 310.

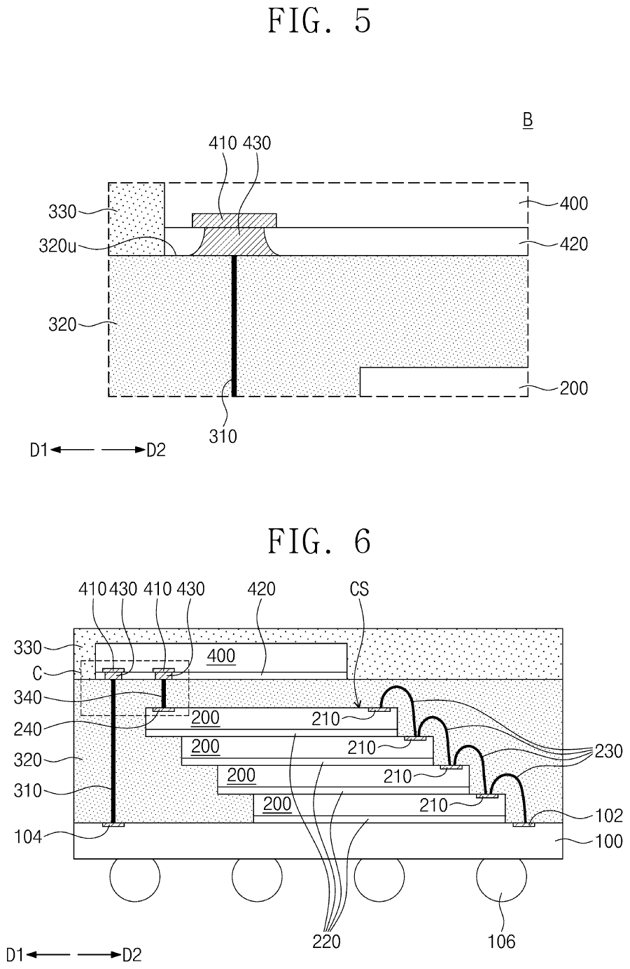

The second connection wire 310 may vertically extend in the first molding film 320. The upper end of the second connection wire 310 may be exposed at a bottom surface of the recess region RS. FIG. 3 illustrates that the upper end of the second connection wire 310 is located at the same level as the bottom surface of the recess region RS, but the inventive concept is not limited thereto. As illustrated in FIG. 4, the second connection wire 310 may protrude upward from the bottom surface of the recess region RS. For example, the upper end of the second connection wire 310 may be located at a higher level than the bottom surface of the recess region RS. The upper end of the second connection wire 310 may be located at a lower level than the upper surface 320u of the first molding film 320.

According to other embodiments, as illustrated in FIG. 5, the upper surface 320u of the first molding film 320 may be a substantially flat surface. For example, the first molding film 320 may not have the recess region RS described with reference to FIGS. 3 and 4. The second connection wire 310 may vertically extend in the first molding film 320. The upper end of the second connection wire 310 may be exposed at the upper surface 320u of the first molding film 320. Terms such as “same,” “equal,” “planar,” “flat,” or “coplanar,” as used herein encompass near identicality including variations that may occur, for example, due to manufacturing processes. The term “substantially” may be used herein to emphasize this meaning, unless the context or other statements indicate otherwise.

Referring to FIG. 1, the first molding film 320 may include an insulating polymer material such as epoxy molding compound (EMC).

A second semiconductor chip 400 may be provided on the first molding film 320. The second semiconductor chip 400 may be disposed on the upper surface 320u of the first molding film 320. The second semiconductor chip 400 may be the same chip as the first semiconductor chips 200. Alternatively, the second semiconductor chip 400 may be a chip different from the first semiconductor chips 200. For example, the second semiconductor chip 400 may be a logic chip or memory chip. The second semiconductor chip 400 may be disposed on the first molding film 320 in a face down form. For example, the second semiconductor chip 400 may have a front surface facing the package substrate 100 and a rear surface opposite to the front surface. The second semiconductor chip 400 may have a second chip pad 410 provided on a lower surface of the second semiconductor chip 400. The second chip pad 410 may be electrically connected to an integrated circuit of the second semiconductor chip 400.

FIG. 1 illustrates that the second semiconductor chip 400 has one second chip pad 410, but only one second chip pad 410 is illustrated in FIG. 1 which is a cross-sectional view, and the second semiconductor chip 400 may have a plurality of second chip pads 410 as needed.

A second adhesive layer 420 may be provided on the lower surface of the second semiconductor chip 400. The second semiconductor chip 400 may be adhered to the upper surface 320u of the first molding film 320 by using the second adhesive layer 420. In this case, the second semiconductor chip 400 may be aligned on the first molding film 320 such that the second chip pad 410 is located on the second connection wire 310. The second adhesive layer 420 may include a die attach film (DAF).

The second semiconductor chip 400 may be electrically connected to the second connection wire 310. For example, a connection terminal 430 may be provided between the first molding film 320 and the second semiconductor chip 400. The connection terminal 430 may be connected to a lower surface of the second chip pad 410 of the second semiconductor chip 400. The connection terminal 430 may penetrate the second adhesive layer 420 to be connected to the upper end of the second connection wire 310.

As illustrated in FIG. 3, when the first molding film 320 has the recess region RS, the connection terminal 430 may be provided in the recess region RS. The connection terminal 430 may fill the recess region RS, and may be in contact with the second connection wire 310 on the bottom surface of the recess region RS. For example, the connection terminal 430 may be provided on the first molding film 320, but may be partially inserted into an inside of the first molding film 320.

Alternatively, as illustrated in FIG. 4, the second connection wire 310 may protrude upward from the bottom surface of the recess region RS. The connection terminal 430 may fill the remaining region of the recess region RS except for the second connection wire 310. For example, the second connection wire 310 may be inserted into an inside of the connection terminal 430 that fills the recess region RS.

Alternatively, as illustrated in FIG. 5, the upper surface 320u of the first molding film 320 may be a substantially flat surface. The upper end of the second connection wire 310 may be exposed at the upper surface 320u of the first molding film 320. For example, the upper end of the second connection wire 310 may be coplanar with the upper surface 320u of the first molding film 320. The connection terminal 430 may be in contact with the upper surface 320u of the first molding film 320. In this case, the connection terminal 430 may be in contact with the upper end of the second connection wire 310 on the upper surface 320u of the first molding film 320. A lower surface of the connection terminal 430 may be substantially flat.

According to embodiments of the inventive concept, the second semiconductor chip 400 may be provided on the first molding film 320 that buries the first semiconductor chips 200 and the second connection wire 310. The second semiconductor chip 400 may be supported by the first molding film 320, the second connection wire 310 and the second semiconductor chip 400 may be more easily connected with each other, and the second connection wire 310 may not be peeled off the second semiconductor chip 400. For example, the semiconductor package with improved structural stability may be provided. This will be described with a method of manufacturing a semiconductor package in more detail.

Referring to FIG. 1, a second molding film 330 may be provided on the first molding film 320. The second molding film 330 may surround the second semiconductor chip 400 on the upper surface 320u of the first molding film 320. The second molding film 330 may completely bury the second semiconductor chip 400. For example, the second semiconductor chip 400 may not be exposed at an upper surface of the second molding film 330. Alternatively, the second semiconductor chip 400 may be exposed at the upper surface of the second molding film 330. The second molding film 330 may include an insulating polymer material such as epoxy molding compound (EMC). The second molding film 330 may be composed of a material different from the first molding film 320. The second molding film 330 may have a higher thermal conductivity than the first molding film 320.

According to embodiments of the inventive concept, the second molding film 330 provided on the semiconductor package may have a high thermal conductivity. In an embodiment, the second molding film 330 may have a higher thermal conductivity than the first molding film 320, and thus the second molding film 330 may serve as a heat sink, thereby dissipating heat generated by the first semiconductor chips 200 and the second semiconductor chip 400. Accordingly, heat generated by the first semiconductor chips 200 and the second semiconductor chip 400 may be easily emitted upward toward the second molding film 330 in the semiconductor package. For example, when the second semiconductor chip 400 includes an element, which emits a large amount of heat, such as the logic chip, the semiconductor package may have improved heat emission efficiency through the second molding film 330. For example, the semiconductor package with improved thermal characteristics may be provided.

Hereinafter, the same reference numerals or symbols will be used for the components described in embodiments of FIGS. 1 to 5, and for convenience of description, duplicate description will be omitted or simply made. For example, differences between embodiments of FIGS. 1 to 5 and those in the following embodiments will be mainly described.

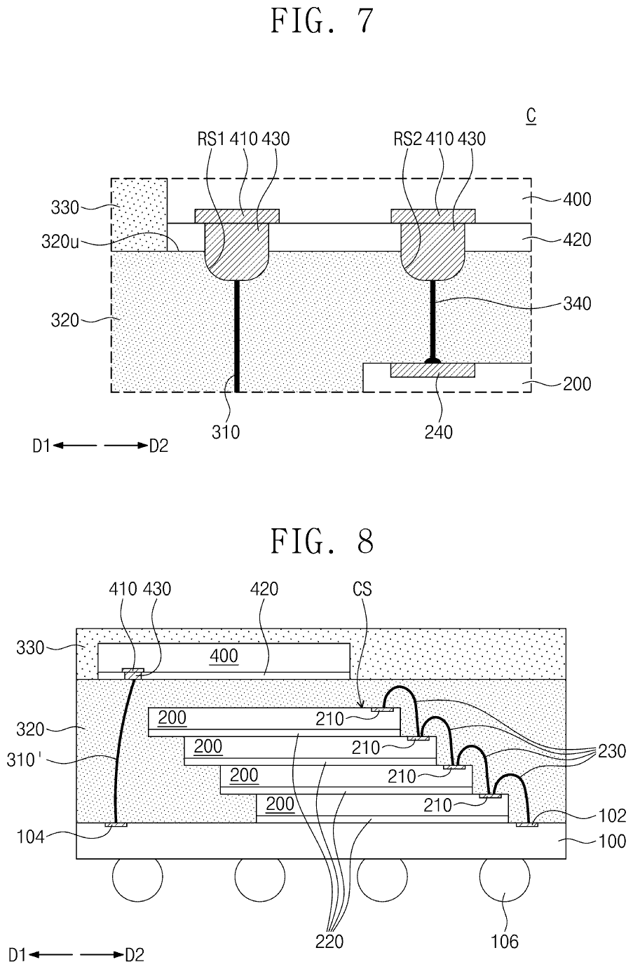

FIG. 6 is a cross-sectional view for describing a semiconductor package according to embodiments of the inventive concept. FIG. 7 is an enlarged diagram of region C of FIG. 6.

Referring to FIGS. 6 and 7, an uppermost first semiconductor chip 200 of the first semiconductor chips 200 of the chip stack CS may further include a third chip pad 240. The third chip pad 240 may be provided on an upper surface of the uppermost first semiconductor chip 200. The third chip pad 240 may be electrically connected to an integrated circuit of the uppermost first semiconductor chip 200. The third chip pad 240 may be disposed horizontally spaced apart from the first chip pad 210.

FIG. 6 illustrates that an uppermost first semiconductor chip 200 has one third chip pad 240, but only one third chip pad 240 is illustrated in FIG. 6 which is a cross-sectional view, and the uppermost first semiconductor chip 200 may have a plurality of third chip pads 240 as needed.

A third connection wire 340 may be provided on the upper surface of the uppermost first semiconductor chip 200. The third connection wire 340 may be connected to the uppermost first semiconductor chip 200. For example, the third connection wire 340 may be connected to the third chip pad 240 of the uppermost first semiconductor chip 200.

As illustrated in FIG. 7, the third connection wire 340 may be bonded to the third chip pad 240 in a stitch bonding manner or a ball bonding manner. For example, the third connection wire 340 may include a bonding portion adhered to an upper surface of the third chip pad 240, and a wire loop extending from the bonding portion to the connection terminal 430.

The third connection wire 340 may extend upward from the upper surface of the third chip pad 240. An angle formed by the third connection wire 340 and the upper surface of the third chip pad 240 may be about 80° to about 90°. An upper end of the third connection wire 340 may be located at a higher level than an uppermost end of the first connection wires 230 provided in the chip stack CS. In an embodiment, the uppermost portion of the third connection wire 340 may be located at a higher level than an uppermost portion of the first connection wires 230 provided in the chip stack CS. The third connection wire 340 may have a greater thickness than the first connection wires 230.

The first molding film 320 may be provided on the package substrate 100. The first molding film 320 may surround the second connection wire 310 and the chip stack CS on the upper surface of the package substrate 100. The first molding film 320 may have a plurality of recess regions. One (this will be referred to as a first recess region RS1) of the recess regions may be located on the second connection wire 310. The other one (this will be referred to as a second recess region RS2) of the recess regions may be located on the third connection wire 340.

The first recess region RS1 may be substantially the same as or similar to the recess region RS described with reference to FIGS. 3 and 4. For example, the second connection wire 310 may be exposed at a bottom surface of the first recess region RS1.

The third connection wire 340 may vertically extend in the first molding film 320. The upper end of the third connection wire 340 may be exposed at a bottom surface of the second recess region RS2. The upper end of the third connection wire 340 may be located at the same level as the bottom surface of the second recess region RS2. Alternatively, the third connection wire 340 may protrude upward beyond the bottom surface of the second recess region RS2. The upper end of the third connection wire 340 may be located at a lower level than the upper surface 320u of the first molding film 320. According to other embodiments, similarly to what is described with reference to FIG. 5, an upper surface of the first molding film 320 may be a flat surface, and the second connection wire 310 and the third connection wire 340 may be exposed at the upper surface of the first molding film 320.

A second semiconductor chip 400 may be disposed on the first molding film 320. The second semiconductor chip 400 may have a plurality of second chip pads 410 provided on a lower surface of the second semiconductor chip 400. The second semiconductor chip 400 may be aligned on the first molding film 320 such that the second chip pads 410 may be respectively located on the second connection wire 310 and the third connection wire 340.

The second semiconductor chip 400 may be electrically connected to the second connection wire 310. The second semiconductor chip 400 may be electrically connected to the third connection wire 340. For example, the connection terminals 430 may be provided between the first molding film 320 and the second semiconductor chip 400. The connection terminals 430 may be connected to a lower surface of the second chip pads 410 of the second semiconductor chip 400. The connection terminals 430 may penetrate the second adhesive layer 420 to be connected to the upper end of the second connection wire 310 and the upper end of the third connection wire 340. For example, one, of the connection terminals 430, connected to the second connection wire 310 may be provided in the first recess region RS1. One, of the connection terminals 430, connected to the third connection wire 340 may be provided in the second recess region RS2.

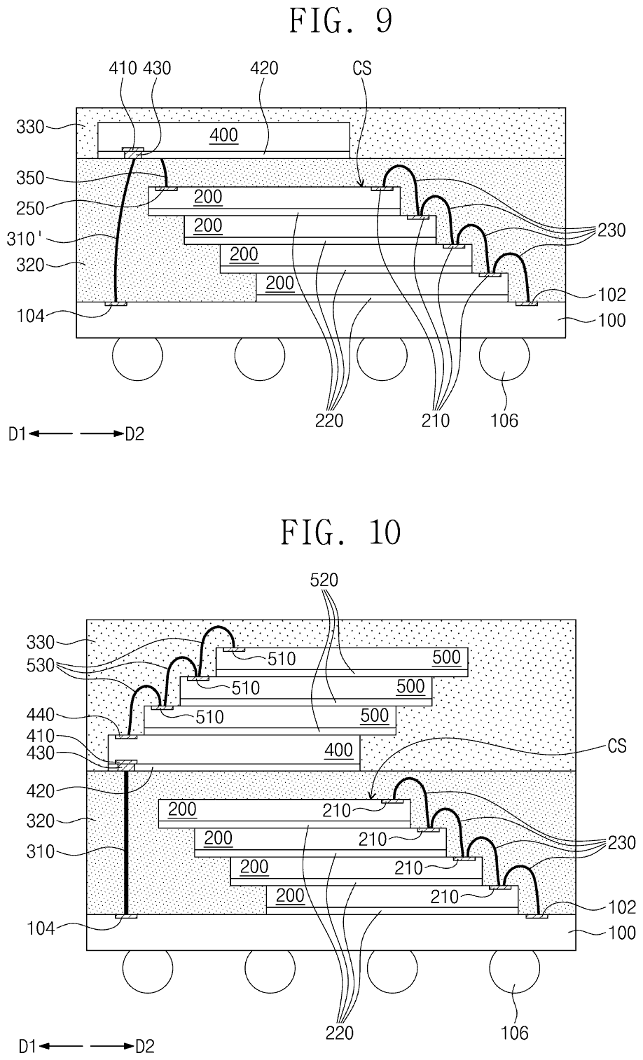

FIGS. 8 and 9 are cross-sectional views for describing a semiconductor package according to embodiments of the inventive concept.

Referring to FIG. 8, a second connection wire 310′ may be provided on an upper surface of the package substrate 100. The second connection wire 310′ may be horizontally spaced apart from the chip stack CS and the first substrate pad 102. The second connection wire 310′ may extend upward from an upper surface of the second substrate pad 104. In this case, on a plan view, a distance between an upper end of the second connection wire 310′ and the chip stack CS may be shorter than a distance between a lower end of the second connection wire 310′ and the chip stack CS. For example, the second connection wire 310′ may have a curve form such that as the second connection wire 310′ extends farther from the package substrate 100, the second connection wire 310′ inclines toward the chip stack CS. The second connection wire 310′ may have a greater thickness than the first connection wires 230. In an embodiment, a shortest distance between a sidewall of an uppermost first semiconductor chip of the first semiconductor chips 200 and the second connection wire 310′ may be smaller than a shortest distance between a sidewall of a lowermost first semiconductor chip of the first semiconductor chips 200 and the second connection wire 310′.

According to other embodiments, as illustrated in FIG. 9, an uppermost first semiconductor chip 200 of the first semiconductor chips 200 of the chip stack CS may further include a dummy chip pad 250. The dummy chip pad 250 may be provided on an upper surface of the uppermost first semiconductor chip 200. The dummy chip pad 250 may be disposed adjacent to the second connection wire 310′.

A dummy wire 350 may be provided on the upper surface of the uppermost first semiconductor chip 200. The dummy wire 350 may be connected to the dummy chip pad 250 of the uppermost first semiconductor chip 200. The dummy wire 350 may be electrically insulated from an integrated circuit of the uppermost first semiconductor chip 200. The dummy wire 350 may be electrically insulated from the second semiconductor chip 400. For example, the dummy wire 350 may be spaced apart from the second semiconductor chip 400 by the second adhesive layer 420. A connection terminal may not be provided between the dummy wire 350 and the second semiconductor chip 400. As used herein, the term “dummy” is used to refer to a component that has the same or similar structure and shape as other components but does not have a substantial function and exists only as a pattern in the device. The dummy chip pad 250 and the dummy wire 350 may refer to non-functional elements that remain after the formation of the second connection wire 310′.

FIG. 10 is a cross-sectional view for describing a semiconductor package according to embodiments of the inventive concept.

Referring to FIG. 10, third semiconductor chips 500 may be provided on the second semiconductor chip 400. The third semiconductor chips 500 may be vertically stacked on the second semiconductor chip 400. The third semiconductor chips 500 may include the same semiconductor chip as the second semiconductor chip 400, or may include different semiconductor chips.

Describing on the basis of one third semiconductor chip 500, a lower surface of the third semiconductor chip 500 may be the rear surface, and an upper surface of the third semiconductor chip 500 may be the front surface. For example, the third semiconductor chip 500 may be disposed in a face up form. The third semiconductor chip 500 may have a fourth chip pad 510 provided on the upper surface. The fourth chip pad 510 may be electrically connected to an integrated circuit of the third semiconductor chip 500.

The second semiconductor chip 400 may further include a rear surface pad 440. The rear surface pad 440 may be disposed on an upper surface of the second semiconductor chip 400.

The second semiconductor chip 400 and the third semiconductor chips 500 may be disposed in an offset stack structure. For example, the second and third semiconductor chips 400 and 500 may be stacked at an incline in a second direction D2, which may be an upward-sloping staircase form (i.e., a cascade form). For example, each of the third semiconductor chips 500 may protrude, in the second direction D2, from another third semiconductor chip 500 or second semiconductor chip 400 located thereunder. The rear surface pad 440 of the second semiconductor chip 400 and the fourth chip pad 510 of the third semiconductor chips 500 may remain exposed and uncovered by the third semiconductor chip 500 disposed thereon.

Third adhesive layers 520 may be respectively provided on the lower surfaces of the third semiconductor chips 500. The third semiconductor chips 500 may be adhered to an upper surface of another third semiconductor chip 500, or the upper surface of the second semiconductor chip 400 located thereunder by using the third adhesive layers 520.

The third semiconductor chips 500 may be wire-bonded to the second semiconductor chip 400. The third semiconductor chips 500 may be connected to the second semiconductor chip 400 through fourth connection wires 530. For example, the fourth connection wires 530 may connect the fourth chip pad 510 of the third semiconductor chips 500 to the rear surface pad 440 of the second semiconductor chip 400.

FIG. 10 illustrates that the third semiconductor chips 500 are stacked and electrically connected with each other by using wire-bonding, but the inventive concept is not limited thereto. According to other embodiments, the third semiconductor chips 500 may be stacked and electrically connected with each other by using vias vertically penetrating the third semiconductor chips 500.

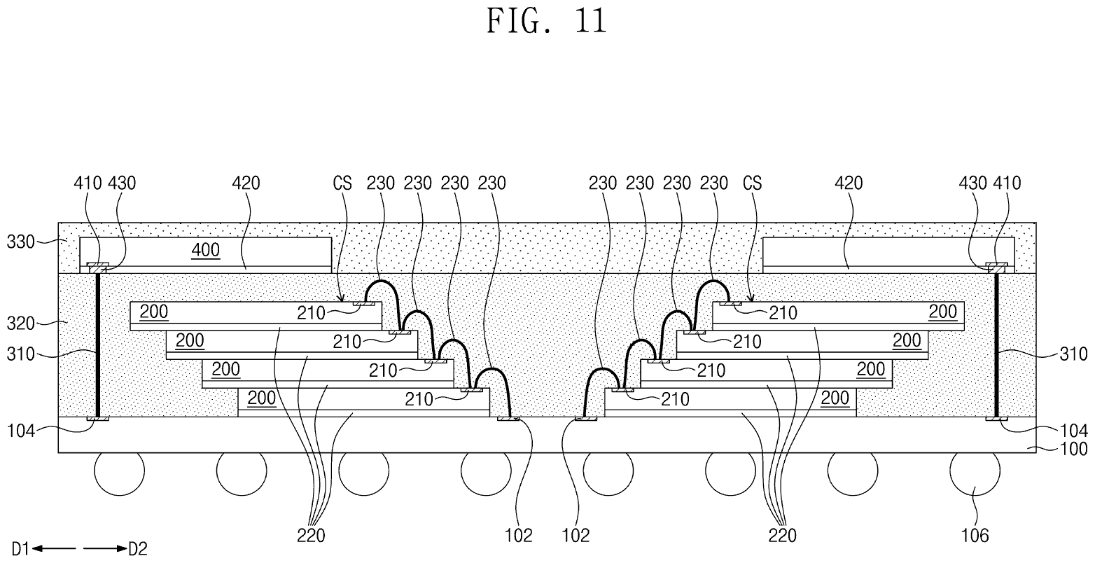

FIG. 11 is a cross-sectional view for describing a semiconductor package according to embodiments of the inventive concept.

Referring to FIG. 11, the semiconductor package may have a plurality of chip stacks CS. Each of the chip stacks CS may be substantially the same as or similar to the chip stack CS described with reference to FIGS. 1 to 10. Each of the chip stacks CS may have the first semiconductor chips 200 vertically stacked, and may be mounted on the package substrate 100 by using the wire-bonding. The chip stacks CS may be embedded in (i.e., encapsulated with) the first molding film 320.

The second semiconductor chip 400 may be provided in plurality on the first molding film 320. Each of the second semiconductor chips 400 may be located on any one of the chip stacks CS. The second semiconductor chips 400 may be disposed on the first molding film 320 and covered by the second molding film 330.

The second connection wire 310 may be provided in plurality. Each of the second connection wires 310 may vertically penetrate the first molding film 320 to connect a corresponding second semiconductor chip of the second semiconductor chips 400 to the package substrate 100. Each of the second semiconductor chips 400 may be connected to a corresponding second connection wire of the second connection wires 310 by using the connection terminal 430 provided on the second chip pad 410 thereof.

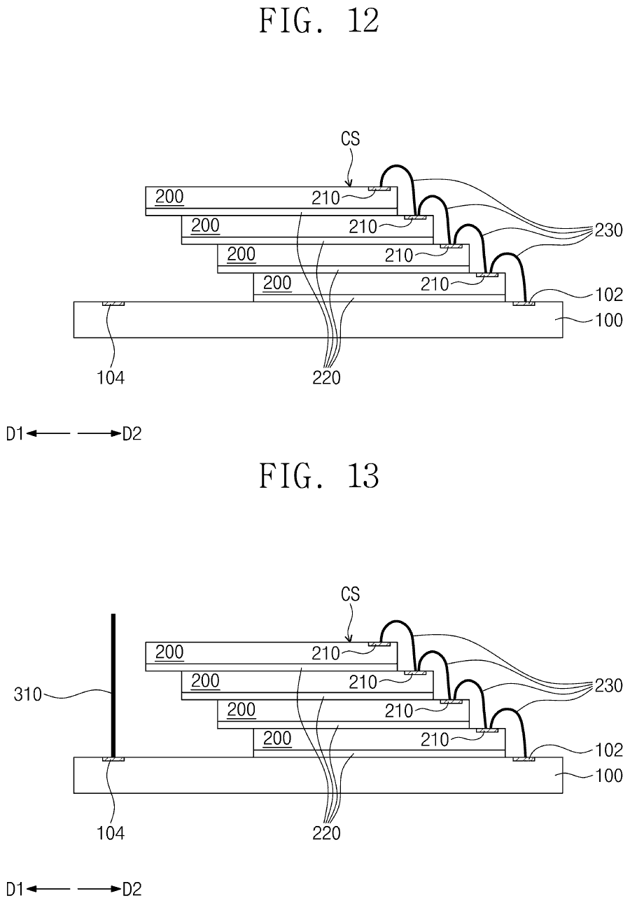

FIGS. 12 to 17 are cross-sectional views for describing a method of manufacturing a semiconductor package according to embodiments of the inventive concept.

Referring to FIG. 12, the package substrate 100 may be provided. The package substrate 100 may include the first and second substrate pads 102 and 104 provided on an upper surface of the package substrate 100.

The first semiconductor chip 200 may be adhered onto the package substrate 100. The first semiconductor chip 200 may be adhered to the package substrate 100 in a face up form. An upper surface of the first semiconductor chip 200 may be an active surface. The first semiconductor chip 200 may be adhered to the package substrate 100 by using the first adhesive layer 220. For example, the first adhesive layer 220 may be provided on a lower surface of the first semiconductor chip 200, and may adhere the first semiconductor chip 200 to the upper surface of the package substrate 100.

Other first semiconductor chips 200 may be stacked on the first semiconductor chip 200. The process of adhering other first semiconductor chips 200 may be the same as or similar to a process of adhering one of the first semiconductor chips 200 to the package substrate 100.

The first semiconductor chips 200 may adhered shifted in the first direction D1 from the first semiconductor chip 200 located thereunder. For example, the first chip pad 210 of each of the first semiconductor chips 200 may remain exposed and uncovered by another first semiconductor chip 200 located thereon.

The first semiconductor chips 200 may be wire-bonded onto the package substrate 100. The first semiconductor chips 200 may be connected to the package substrate 100 through first connection wires 230. For example, the first connection wires 230 may connect the first chip pads 210 of the first semiconductor chips 200 to the first substrate pads 102 of the package substrate 100.

Referring to FIG. 13, the second connection wire 310 may be formed on the second substrate pad 104. For example, the second connection wire 310 may be formed through a metal wire bonding process. The metal wire bonding process may include, for example, coupling a metal wire to a bonding apparatus, for example, a capillary, placing the metal wire on the second substrate pad 104, attaching the bonding portion 312 (see FIG. 2) of the metal wire to the second substrate pad 104 by lowering the capillary, forming the wire loop 314 by pulling the metal wire from the bonding portion 312 in a vertical direction by raising the capillary, and cutting the metal wire. The bonding portion 312 having a ball shape of FIG. 2 may be formed in the process of bonding the metal wire to the second substrate pad 104. The second connection wire 310 may have a diameter of about 30 μm or less. An upper end of the second connection wire 310 (i.e., an upper end of the wire loop 314) may be located at a higher level than an uppermost end of the first connection wires 230. In an embodiment, the uppermost portion of the second connection wire 310 may be located at a higher level than an uppermost portion of the first connection wires 230 provided in the chip stack CS. The second connection wire 310 may have a greater thickness than the first connection wires 230.

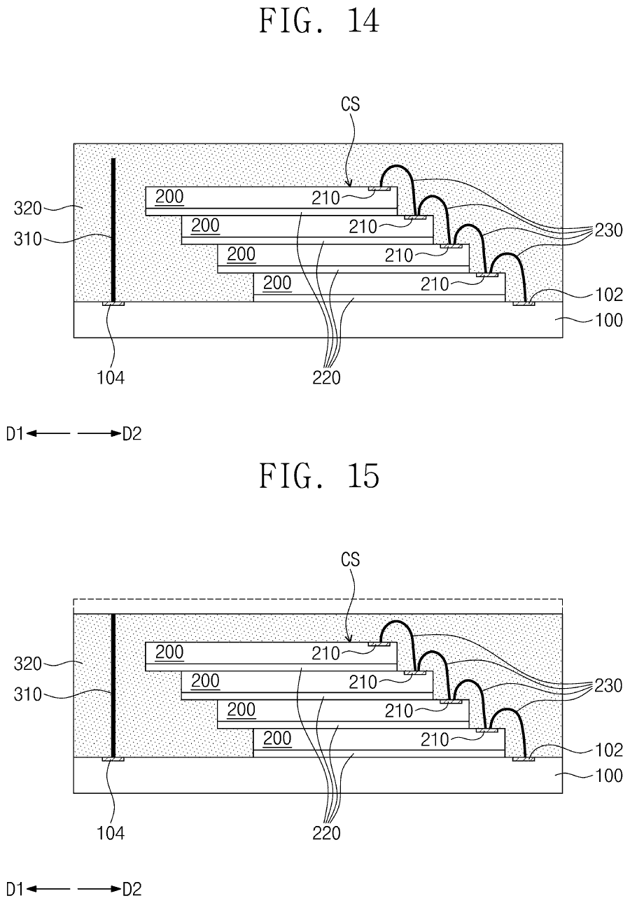

Referring to FIG. 14, the first molding film 320 may be formed on the package substrate 100. For example, a molding material may be applied so as to bury the chip stacks CS and the second connection wire 310 on the upper surface of the package substrate 100, and the molding material may be cured to form the first molding film 320.

Referring to FIG. 15, a thinning process may be performed on the first molding film 320. The thinning process may include a chemical mechanical polishing (CMP) process or a grinding process. An upper surface of the first molding film 320 may be lowered by the thinning process. The thinning process may be performed until the upper surface of the second connection wire 310 is exposed. During the thinning process, an upper portion of the second connection wire 310 may be partially removed. During the thinning process, the first connection wires 230 may not be exposed.

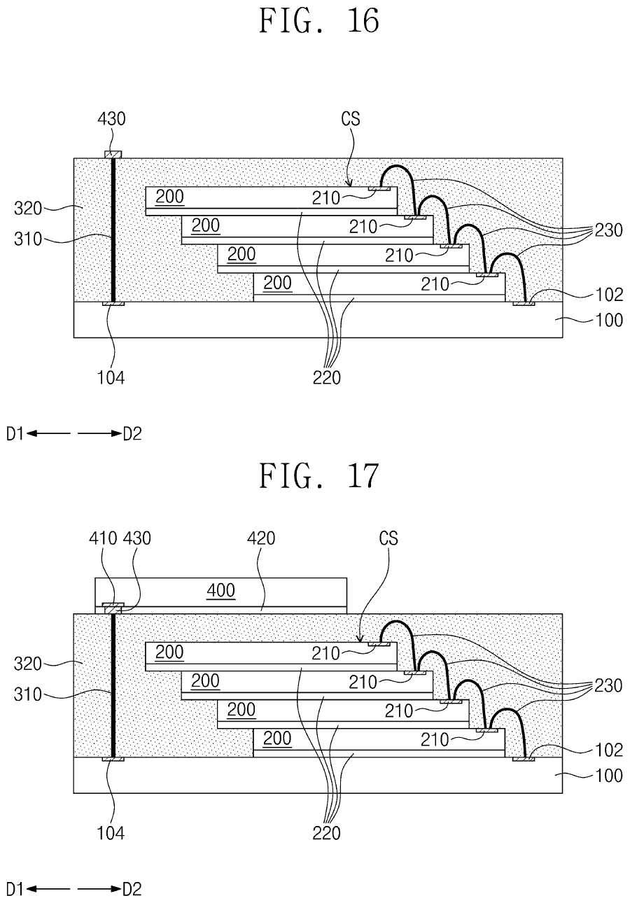

Referring to FIG. 16, the connection terminal 430 may be formed on the first molding film 320. For example, after forming, on the first molding film 320, a mask film exposing the second connection wire 310, the connection terminal 430 may be formed by filling a pattern (i.e., an opening) of the mask film with a solder material. The solder material may be connected to the second connection wire 310 formed at the upper surface of the first molding film 320. Alternatively, the connection terminal 430 may be formed by supplying, on the first molding film 320, solder paste so as to be in contact with the second connection wire 310.

Referring to FIG. 17, the second semiconductor chip 400 may be provided. The second semiconductor chip 400 may be substantially the same as or similar to the second semiconductor chip 400 described with reference to FIGS. 1 to 11.

The second adhesive layer 420 may be provided on the lower surface of the second semiconductor chip 400. The second chip pad 410 of the second semiconductor chip 400 may be covered by the second adhesive layer 420.

The second semiconductor chip 400 may be disposed on the first molding film 320. In this case, the second chip pad 410 may be located on a lower surface of the second semiconductor chip 400 facing the first molding film 320. The second semiconductor chip 400 may be aligned on the first molding film 320 such that the second chip pad 410 faces the connection terminal 430.

The second semiconductor chip 400 may be lowered so that the second adhesive layer 420 is in contact with the upper surface of the first molding film 320. The second adhesive layer 420 may adhere the upper surface of the first molding film 320 to the lower surface of the second semiconductor chip 400. In this case, the connection terminal 430 may be inserted into an inside of the second adhesive layer 420, and may be in contact with the second chip pad 410.

A reflow process of the connection terminal 430 may be performed. During the reflow process, the connection terminal 430 may be melted and then solidified. During the reflow process, the connection terminal 430 may be melted to connect the second connection wire 310 to the second chip pad 410. In this case, the melted connection terminal 430 may partially flow along an upper surface of the first molding film 320.

According to embodiments of the inventive concept, before connecting the second semiconductor chip 400 onto the second connection wire 310, the second connection wire 310 may be embedded inside (i.e., may be encapsulated with) the first molding film 320. Accordingly, the second connection wire 310 may not be moved or transformed in the disposition or reflow process of the second semiconductor chip 400. For example, defects such as misplacement of the second connection wire 310 due to movement of the second semiconductor chip 400 and transformation of the second connection wire 310 due to application of heat may not occur. For example, the method of manufacturing a semiconductor package with low occurrence of the defect may be provided.

When the second semiconductor chip 400 is disposed and electrically connected, the second semiconductor chip 400 may be supported by an upper surface of the first molding film 320. Accordingly, the second semiconductor chip 400 may be disposed more stably, and the semiconductor package with improved structural stability may be manufactured.

Referring to FIGS. 1 and 2, the second molding film 330 may be formed on the first molding film 320. For example, a molding material may be applied so as to bury the second semiconductor chip 400 on the upper surface of the first molding film 320, and the molding material may be cured to form the second molding film 330.

Thereafter, the external terminals 106 may be provided on the lower surface of the package substrate 100.

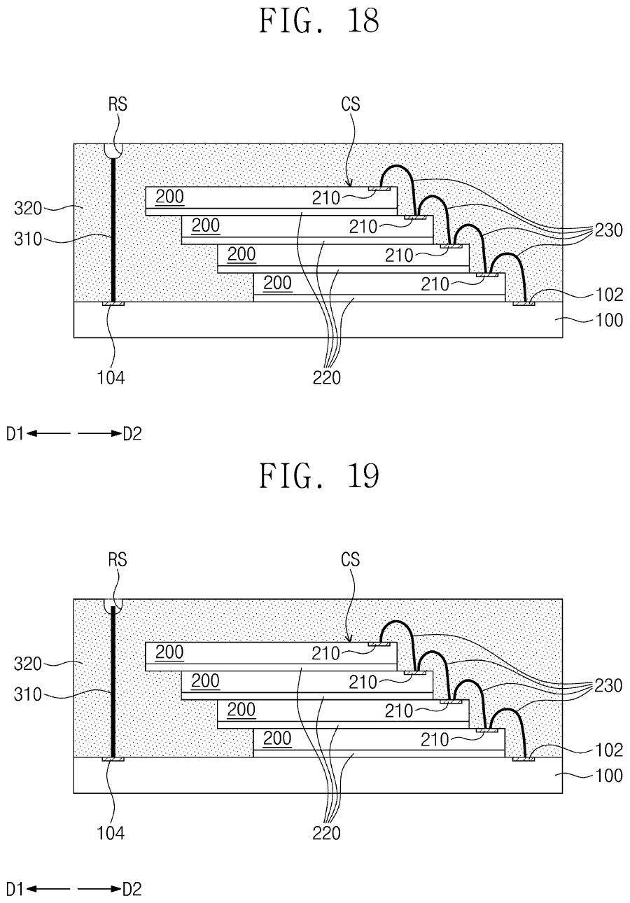

FIGS. 18 to 20 are cross-sectional views for describing a method of manufacturing a semiconductor package according to embodiments of the inventive concept.

Referring to FIG. 18, on the resulting structure of FIG. 14, the recess region RS may be formed on the first molding film 320. For example, a mask film may be formed on the first molding film 320. The mask film may have a pattern (i.e., an opening) exposing an upper surface of the first molding film 320. The pattern may be located on the second connection wire 310. The recess region RS may be formed by performing an etching process on the upper surface of the first molding film 320 exposed by the pattern. The etching process may be performed until an upper end of the second connection wire 310 is exposed. The upper end of the second connection wire 310 may be exposed at a bottom surface of the recess region RS. The upper end of the second connection wire 310 may be located at the same level as the bottom surface of the recess region RS.

According to other embodiments, referring to FIG. 19, after the second connection wire 310 is exposed at the bottom surface of the recess region RS, the etching process may also be continuously performed. Accordingly, the recess region RS may become deeper. The second connection wire 310 may not be etched during the etching process. Accordingly, the second connection wire 310 may protrude upward beyond the bottom surface of the recess region RS. In this case, the semiconductor package described with reference to FIG. 4 may be manufactured. Hereinafter, description will be continuously made with respect to FIG. 18.

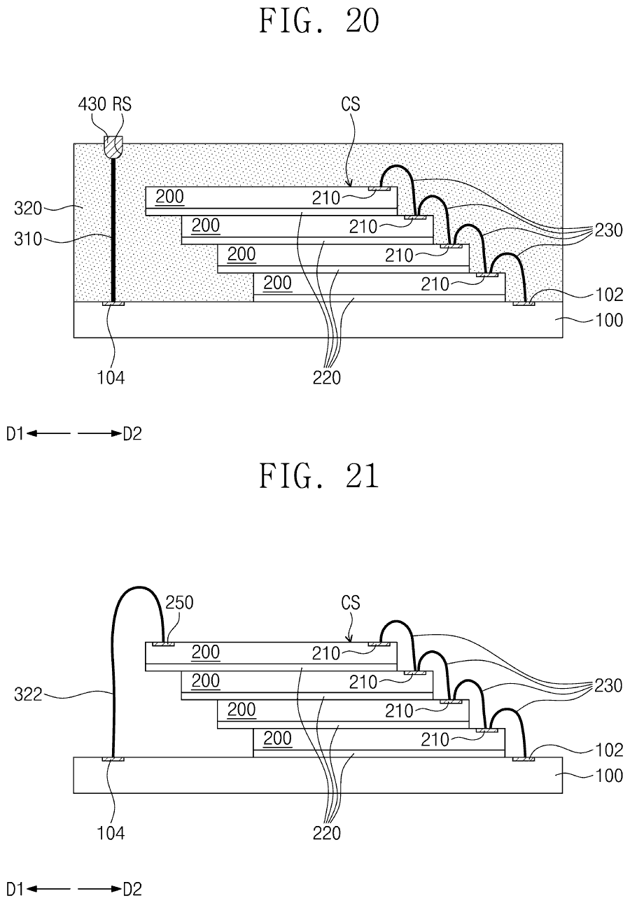

Referring to FIG. 20, the connection terminal 430 may be formed on the first molding film 320. For example, after forming, on the first molding film 320, a mask film exposing the recess region RS, the connection terminal 430 may be formed by filling the recess region RS with a solder material. Alternatively, the connection terminal 430 may be formed by supplying solder paste to the recess region RS. An upper end of the connection terminal 430 may be located at a higher level than the upper surface of the first molding film 320. For example, the connection terminal 430 may protrude upward beyond the upper surface of the first molding film 320.

Thereafter, the process described with reference to FIG. 17 may be performed. For example, the second semiconductor chip 400 may be adhered onto the first molding film 320 by using the second adhesive layer 420. Thereafter, the connection terminal 430 may connect the second connection wire 310 to the second chip pad 410 by performing the reflow process.

Referring to FIGS. 1 and 3, the second molding film 330 may be formed on the first molding film 320. The external terminals 106 may be provided on the lower surface of the package substrate 100.

FIGS. 21 to 23 are cross-sectional views for describing a method of manufacturing a semiconductor package according to embodiments of the inventive concept.

Referring to FIG. 21, the resulting structure of FIG. 12 may be provided. In this case, an uppermost first semiconductor chip 200 of the first semiconductor chips 200 of the chip stack CS may further have the dummy chip pad 250. The dummy chip pad 250 may be the same as or similar to what is described with reference to FIG. 9.

The uppermost first semiconductor chip 200 may be wire bonded. For example, the uppermost first semiconductor chip 200 may be connected to the second substrate pad 104 of the package substrate 100. For example, one end of a preliminary connection wire 322 may be connected to the dummy chip pad 250 of the uppermost first semiconductor chip 200. The other end of the preliminary connection wire 322 may be connected to the second substrate pad 104. In this case, an angle formed by the second substrate pad 104 and the preliminary connection wire 322 may be about 80° to about 90°. An uppermost end of the preliminary connection wire 322 may be located at a higher level than uppermost ends of the first connection wires 230. In an embodiment, an uppermost portion of the preliminary connection wire 322 may be located at a higher level than an uppermost portion of the first connection wires 230.

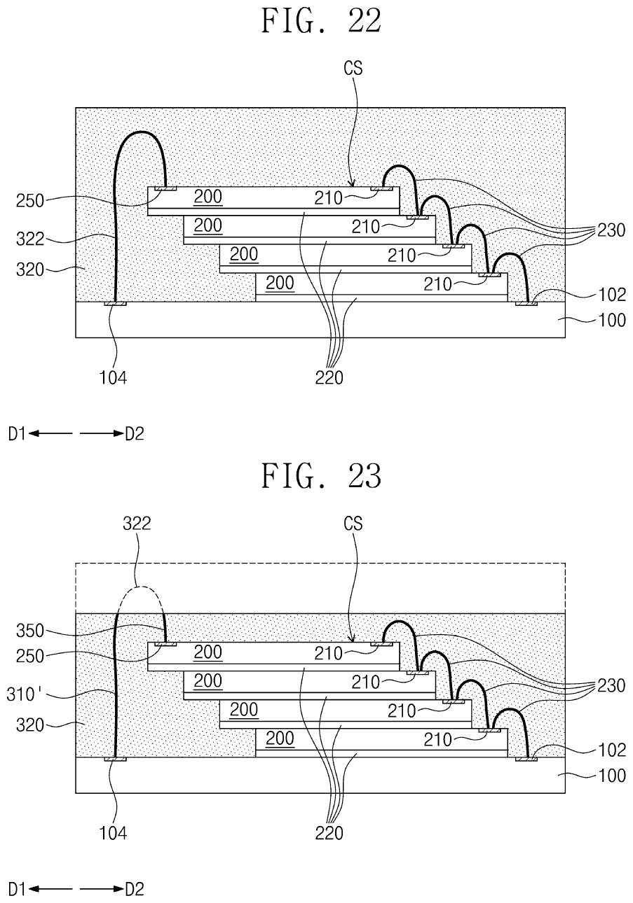

Referring to FIG. 22, the first molding film 320 may be formed on the package substrate 100. For example, a molding material may be applied so as to bury the chip stacks CS and the preliminary connection wire 322 on the upper surface of the package substrate 100, and the molding material may be cured to form the first molding film 320.

Referring to FIG. 23, a thinning process may be performed on the first molding film 320. The thinning process may include a chemical mechanical polishing (CMP) process or a grinding process. An upper surface of the first molding film 320 may be lowered by the thinning process. The preliminary connection wire 322 may be exposed during the thinning process. During the thinning process, an exposed upper portion of the preliminary connection wire 322 may be partially removed. Accordingly, the preliminary connection wire 322 may be separated into the second connection wire 310′ connected to the second substrate pad 104 and the dummy wire 350 connected to the dummy chip pad 250. The second connection wire 310′ may extend upward from the second substrate pad 104, and the dummy wire 350 may extend upward from the dummy chip pad 250. One end of the second connection wire 310′ and one end of the dummy wire 350 may be exposed at the upper surface of the first molding film 320. The thinning process may be performed until before the chip stack CS is exposed. For example, the chip stack CS may be embedded in (i.e., may be encapsulated with) the first molding film 320, and may not be exposed at the upper surface of the first molding film 320.

Thereafter, the processes described with reference to FIGS. 16 and 17 may be performed. For example, the connection terminal 430 connected to one end of the second connection wire 310′ may be formed on the first molding film 320. The second semiconductor chip 400 may be adhered onto the first molding film 320 by using the second adhesive layer 420. Thereafter, the connection terminal 430 may connect the second connection wire 310 to the second chip pad 410 by performing the reflow process.

Referring to FIG. 9, the second molding film 330 may be formed on the first molding film 320. The external terminals 106 may be provided on the lower surface of the package substrate 100.

In a semiconductor package according to embodiments of the inventive concept, a second semiconductor chip may be provided on a first molding film that buries first semiconductor chips and a second connection wire. The second semiconductor chip may be supported by the first molding film, the second connection wire and the second semiconductor chip may be more easily connected with each other, and the second connection wire may not be peeled off the second semiconductor chip. For example, the semiconductor package with improved structural stability may be provided.

A second molding film provided on the semiconductor package may have a high thermal conductivity. Accordingly, heat generated by the first semiconductor chips and the second semiconductor chip may be easily emitted upward toward the second molding film in the semiconductor package. For example, when the second semiconductor chip includes an element, that emits a large amount of heat, such as a logic chip, the semiconductor package may have improved heat emission efficiency through the second molding film. For example, the semiconductor package with improved thermal characteristics may be provided.

In a method of manufacturing a semiconductor package according to embodiments of the inventive concept, before connecting the second semiconductor chip onto the second connection wire, the second connection wire may be embedded inside (i.e., may be encapsulated with) the first molding film. Accordingly, the second connection wire may not be moved or transformed in a disposition or reflow process of the second semiconductor chip. For example, the method of manufacturing a semiconductor package with low occurrence of a defect may be provided.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor package comprising:
a package substrate;
a chip stack having a plurality of first semiconductor chips stacked on the package substrate;
a first molding film covering the chip stack on the package substrate;
a first connection wire vertically penetrating the first molding film and connected to the package substrate, wherein the first connection wire is exposed at an upper surface of the first molding film;
a second semiconductor chip disposed on the first molding film, and having a lower surface and a first chip pad, wherein the first chip pad is disposed at the lower surface of the second semiconductor chip;
a second molding film disposed on the first molding film and covering the second semiconductor chip; and
a first connection terminal connecting the first chip pad to an upper end of the first connection wire.

2. The semiconductor package of claim 1,
wherein the upper surface of the first molding film has a recess region recessed from the upper surface of the first molding film toward a lower surface of the first molding film, and
wherein the upper end of the first connection wire is exposed at a bottom surface of the recess region.

3. The semiconductor package of claim 2,
wherein the first connection terminal is provided in the recess region.

4. The semiconductor package of claim 1,
wherein the upper surface of the first molding film is a substantially flat surface, and
wherein the upper end of the first connection wire is exposed at the substantially flat surface.

5. The semiconductor package of claim 4,
wherein the first connection terminal contacts the substantially flat surface and the upper end of the first connection wire, and
wherein a lower surface of the first connection terminal is substantially flat.

6. The semiconductor package of claim 1,
wherein each first semiconductor chip of the plurality of first semiconductor chips has an upper surface and a second chip pad provided at the upper surface of each first semiconductor chip, and
wherein the chip stack further comprises a plurality of second connection wires connecting the plurality of first semiconductor chips and the package substrate with each other.

7. The semiconductor package of claim 6,
wherein the first connection wire has a greater thickness than each second connection wire of the plurality of second connection wires.

8. The semiconductor package of claim 6,
wherein a shortest distance between the first connection wire and a sidewall of an uppermost first semiconductor chip of the plurality of first semiconductor chips is smaller than a shortest distance between the first connection wire and a sidewall of a lowermost first semiconductor chip of the plurality of first semiconductor chips.

9. The semiconductor package of claim 1, further comprising:
a third connection wire vertically penetrating the first molding film and connected to an uppermost first semiconductor chip of the plurality of first semiconductor chips of the chip stack, wherein the third connection wire is exposed at the upper surface of the first molding film; and
a second connection terminal connecting the second semiconductor chip to an upper end of the third connection wire.

10. The semiconductor package of claim 1,
wherein the second molding film has a greater thermal conductivity than the first molding film.

11. The semiconductor package of claim 1, further comprising:
an adhesive film provided on the lower surface of the second semiconductor chip, and attaching the second semiconductor chip to the upper surface of the first molding film,
wherein the first connection terminal penetrates the adhesive film to be connected to the first chip pad.

12. A semiconductor package comprising:
a package substrate;
a chip stack including a plurality of first semiconductor chips stacked on the package substrate;
a first molding film disposed on the package substrate and encapsulating the chip stack;
a second semiconductor chip disposed on the first molding film;
a second molding film disposed on the first molding film and encapsulating the second semiconductor chip;
a first connection wire vertically penetrating the first molding film, and electrically connected to the second semiconductor chip;
a plurality of external terminals connected to a lower surface of the package substrate,
wherein the chip stack is spaced apart from the first connection wire in a horizontal direction parallel to an upper surface, opposite to the lower surface, of the package substrate, and
wherein each first semiconductor chip of the plurality of first semiconductor chips has an upper surface and a chip pad disposed at the upper surface of each first semiconductor chip; and
a plurality of second connection wires connecting the plurality of chip pads of the plurality of the first semiconductor chips with each other.

13. The semiconductor package of claim 12,
wherein the first connection wire vertically penetrates the first molding film and electrically connected to the package substrate,
wherein the first connection wire is exposed at an upper surface of the first molding film, and
wherein the second semiconductor chip is connected to the first connection wire through a connection terminal disposed on the first molding film.

14. The semiconductor package of claim 13,
wherein the upper surface of the first molding film has a recess region recessed from the upper surface of the first molding film toward a lower surface of the first molding film, and
wherein an upper end of the first connection wire is exposed at a bottom surface of the recess region.

15. The semiconductor package of claim 14,
wherein the connection terminal is provided in the recess region.

16. The semiconductor package of claim 14,
wherein the upper surface of the first molding film is a substantially flat surface,
wherein a lower surface of the connection terminal contacts the upper surface of the first molding film and the upper end of the first connection wire, and
wherein the lower surface of the connection terminal is substantially flat.

17. The semiconductor package of claim 12,
wherein the first connection wire has a greater thickness than each of the plurality of second connection wires.

18. The semiconductor package of claim 12,
wherein the second molding film has a greater thermal conductivity than the first molding film.

19. A semiconductor package comprising:
a package substrate;
a chip stack having a plurality of first semiconductor chips stacked on an upper surface of the package substrate, and a plurality of first connection wires connecting the plurality of first semiconductor chips;
a second connection wire disposed on the upper surface of the package substrate, spaced apart from the chip stack in a horizontal direction parallel to the upper surface of the package substrate, and connected to a substrate pad of the package substrate;
a first molding film disposed on the upper surface of the package substrate and encapsulating the chip stack and the second connection wire;
a second semiconductor chip disposed on the first molding film, and connected to an upper end of the second connection wire by using a solder member; and
a second molding film disposed on the first molding film and encapsulating the second semiconductor chip.

20. The semiconductor package of claim 19,
wherein the solder member is disposed between the second semiconductor chip and the first molding film, and wherein the solder member is at least partially inserted into an inside of the first molding film.
